(19) United States
(12) Patent Application Publication
(10) Pub. No.: US 2025/0294287 A1
(43) Pub. Date: Sep. 18, 2025

(54) SYSTEM AND METHOD FOR DUAL MICROPHONE WITH CALIBRATED ALGORITHM TO WIDEN SPEECH OUTPUT RANGE FOR A HEADSET DEVICE

(71) Applicant: Dell Products LP, Round Rock, TX (US)

(72) Inventors: You-Yu Lin, Sanchong Dist. (TW); Eng Kang Chng, Singapore (SG); Peng Lip Goh, Singapore (SG)

(73) Assignee: Dell Products LP, Round Rock, TX (US)

(21) Appl. No.: 18/607,898

(22) Filed: Mar. 18, 2024

(51) Int. Cl. H04R 3/00; G10L 21/0208; G10L 21/034; H03G 3/30; H04R 1/08; H04R 1/10

(52) U.S. Cl. CPC H04R 3/005; G10L 21/034; H03G 3/3089; H04R 1/083; H04R 1/1008; G10L 2021/02082

(57) ABSTRACT

A headset device including a headset microphone system having a first microphone to receive voice input from a user at a first speech decibel range, and a second microphone to receive the voice input from at a second speech decibel range and a digital signal microprocessor executing computer-readable program code of a dual microphone audio mixing module to mix the voice input from each of the first microphone and second microphone to a mixed audio output when the voice input detected at the first microphone exceeds a low decibel range threshold and falls below a high decibel range threshold at the second microphone and the digital signal processor generates a first audio output when the voice input detected at the first microphone falls below the low decibel range threshold and a second audio output when the voice input detected at the second microphone falls exceeds the high decibel range threshold.

### FIELD OF THE DISCLOSURE

The present disclosure generally relates to audio input range at a headset microphone system. More specifically, the present specification describes a headset microphone system that includes two microphones that, via execution of a dual microphone audio mixing module and a low and high threshold detection module, increases the speech output range output from the headset microphone system.

### BACKGROUND

As the value and use of information continues to increase, individuals and businesses seek additional ways to process and store information. One option available to clients is information handling systems. An information handling system generally processes, compiles, stores, and/or communicates information or data for business, personal, or other purposes thereby allowing clients to take advantage of the value of the information. Because technology and information handling may vary between different clients or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific client or specific use, such as e-commerce, financial transaction processing, airline reservations, enterprise data storage, or global communications. In addition, information handling systems may include a variety of hardware and software components that may be configured to process, store, and communicate information and may include one or more computer systems, data storage systems, and networking systems. The information handling system may include telecommunication, network communication, and video communication capabilities. The information handling system may be used to execute instructions of one or more applications such as a gaming application. Further, the information handling system may include a headset microphone used to receive audio input from a user of the information handling system.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram illustrating an information handling system including a headset microphone system that includes dual microphones used to increase speech range according to an embodiment of the present disclosure;

FIG. 2 is a diagram depicting a headset with a headset microphone system that includes dual microphones used to increase speech range according to an embodiment of the present disclosure;

FIG. 3 is a diagram depicting speech ranges of a dual headset microphone system and showing the resulting increase in speech output range according to an embodiment of the present disclosure;

FIG. 4 is a graph showing input from a first microphone, input from a second microphone and a range within the inputs of the first microphone and second microphone where audio from each microphone is mixed via execution of a dual microphone audio mixing module at a headset microphone system according to an embodiment of the present disclosure; and

FIG. 5 is a flow chart showing a method of increasing a speech output range of a headset microphone system according to another embodiment of the present disclosure.

The use of the same reference symbols in different drawings may indicate similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Information handling systems include a plurality of input and output devices that allow a user to interact with the information handling system. The types of input may include cursor movement and selection input from a mouse and/or trackpad, keystroke input from a keyboard, and audio input from a microphone such as a microphone as part of a headset. The microphone, for example, allows a user to engage in a discussion with another user remote from the information handling system during a videoconferencing session or an online gaming session. Input capabilities of a single microphone, however, are limited. For example, a microphone has limited input speech levels, microphone sensitivity levels, signal-to-noise ratios (SNR), acoustic overload point levels (AOP), and dynamic range control (DRC) levels coupled with high gain and floor noise levels. Indeed, these constraints presented by a single microphone used to provide input to an information handling system lead to high distorted outputs especially in those situations where speech inputs exceed the AOPs, the DRC levels, floor noise levels, and microphone sensitivity levels.

The present specification describes a headset microphone system used to provide input to the information handling system or output from an information handling system 100. The headset microphone system includes a first microphone and a second microphone that allows the headset microphone system to increase existing DRC levels and SNR levels and also minimizes distortion with lower floor noise levels. In an embodiment, a digital signal processor of the headset microphone system that executes computer-readable program code of a dual microphone audio mixing module to mix input from each of the first microphone and second microphone when the audio detected at the first microphone exceeds a low decibel range threshold and the audio detected at the second microphone falls below a high decibel range threshold. In an embodiment, the low decibel range threshold is 90 decibels and the high decibel range threshold is 70 decibels and wherein the execution of the computer-readable program code of the dual microphone audio mixing module by the digital signal microprocessor at the headset mixes input from each of the first microphone and second microphone, such as a dual boom microphone situated before a user's mouth, that falls between the low decibel range threshold and the high decibel range threshold while outputting the audio stream from the first microphone that falls below the low decibel range threshold and the audio stream from the second microphone that exceeds the high decibel range threshold to an operatively coupled to the information handling system. In this way, audio input into the headset microphone system with first and second microphone may have a broader range without distortion when played later or at a remote speaker location.

In an embodiment, the headset microphone system further includes a high gain amplifier operatively coupled to the first microphone to increase the amplitude of the signal received at the first microphone and a first dynamic range controller operatively coupled to the high gain amplifier to set the low decibel range threshold for the first microphone. Still further, the headset microphone system includes a low gain amplifier operatively coupled to the second microphone to increase the amplitude of the signal received at the second microphone and a second dynamic range controller operatively coupled to the low gain amplifier to set the high decibel range threshold for the second microphone.

In an embodiment, the headset microphone system includes computer-readable program code of a low and high threshold detection module that, when executed by the digital signal microprocessor, detects when audio detected at the first microphone exceeds a low decibel range threshold and the audio detected at the second microphone falls below a high decibel range and cause the dual microphone audio mixing module to mix input from each of the first microphone and second microphone. Other modules execute at the digital signal microprocessor including an anti-echo cancelation and noise reduction module to process the output from the dual microphone audio mixing module to reduce echo and noise present in the audio stream from the first microphone and second microphone and an automatic gain control module to maintain a signal output from the anti-echo cancelation and noise reduction module of the headset microphone system operatively coupled to the information handling system.

In an embodiment, a headset microphone system may be formed into a housing of the information handling system with the digital signal microprocessor being operatively coupled to a bus of the information handling system. In an alternative embodiment, the headset microphone system may be formed into a headset that includes a headband, a first earpiece coupled to one end of the headband, a second earpiece coupled to a second end of the headband, and a mouthpiece or other microphone boom having both the first and second microphones oriented in front of a user's mouth and that are operatively coupled to both or one of the first earpiece or second earpiece of the headset.

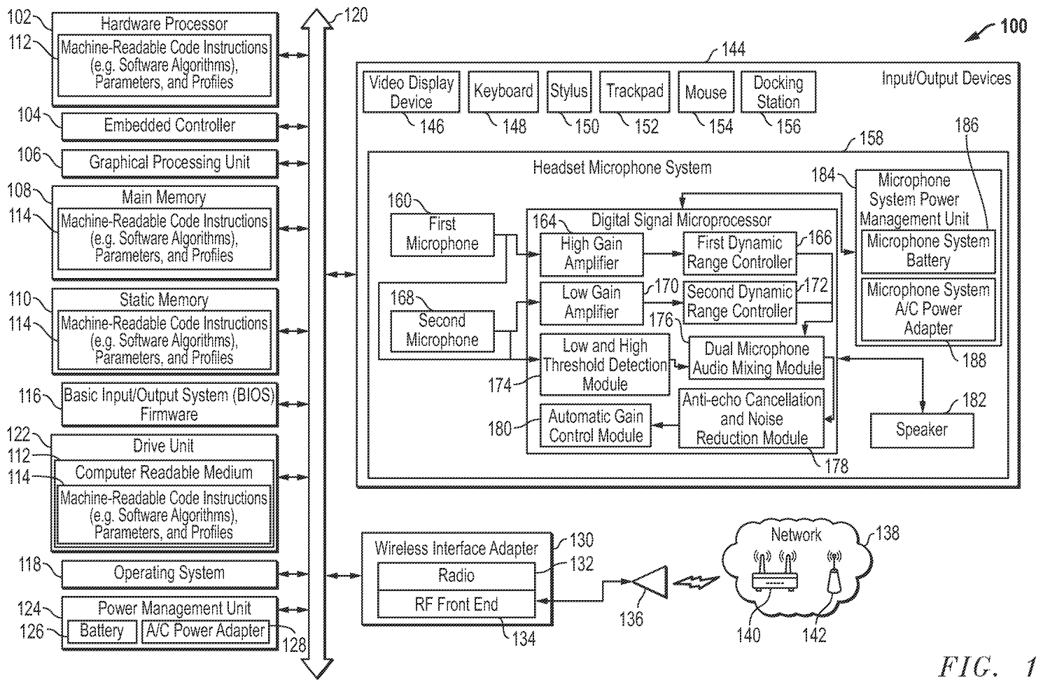

Turning now to the figures, FIG. 1 illustrates an information handling system 100 similar to the information handling systems according to several aspects of the present disclosure. In the embodiments described herein, an information handling system 100 includes any instrumentality or aggregate of instrumentalities operable to compute, classify, process, transmit, receive, retrieve, originate, switch, store, display, manifest, detect, record, reproduce, handle, or use any form of information, intelligence, or data for business, scientific, control, entertainment, or other purposes. For example, an information handling system 100 may be a personal computer, mobile device (e.g., personal digital assistant (PDA) or smart phone), server (e.g., blade server or rack server), a consumer electronic device, a network server or storage device, a network router, switch, or bridge, wireless router, or other network communication device, a network connected device (cellular telephone, tablet device, etc.), IoT computing device, wearable computing device, a set-top box (STB), a mobile information handling system, a palmtop computer, a laptop computer, a desktop computer, a communications device, an access point (AP) 140, a base station transceiver 142, a wireless telephone, a control system, a camera, a scanner, a printer, a personal trusted device, a web appliance, or any other suitable machine capable of executing a set of instructions (sequential or otherwise) that specify actions to be taken by that machine, and may vary in size, shape, performance, price, and functionality.

In a networked deployment, the information handling system 100 may operate in the capacity of a client computer in a server-client network environment, or as a peer computer system in a peer-to-peer (or distributed) network environment. In an embodiment, the information handling system 100 may be implemented using electronic devices that provide voice, video, or data communication. For example, an information handling system 100 may be any mobile or other computing device capable of executing a set of instructions (sequential or otherwise) that specify actions to be taken by that machine. Further, while a single information handling system 100 is illustrated, the term “system” shall also be taken to include any collection of systems or sub-systems that individually or jointly execute a set, or plural sets, of instructions to perform one or more computer functions.

The information handling system 100 may include main memory 108, (volatile (e.g., random-access memory, etc.), or static memory 110, nonvolatile (read-only memory, flash memory etc.) or any combination thereof), one or more hardware processing resources, such as a hardware processor 102 that may be a central processing unit (CPU), embedded controller (EC) 104, a graphics processing unit (GPU) 106, or any combination thereof. Additional components of the information handling system 100 may include one or more storage devices such as static memory 110 or drive unit 122. The information handling system 100 may include or interface with one or more communications ports for communicating with external devices, as well as various input and output (I/O) devices 144, such as a docking station 156, a mouse 154, a trackpad 152, a stylus 150, a keyboard 148, a video/graphics display device 146, a headset microphone system 158, a first microphone 160, a second microphone 168, and a speaker 182, or any combination thereof. Portions of an information handling system 100 may themselves be considered information handling systems 100.

Information handling system 100 may include devices or modules that embody one or more of the devices or execute instructions for one or more systems and modules. The information handling system 100 may execute instructions (e.g., software algorithms), parameters, and profiles 114 that may operate on servers or systems, remote data centers, or on-box in individual client information handling systems according to various embodiments herein. In some embodiments, it is understood any or all portions of instructions (e.g., software algorithms), parameters, and profiles 114 may operate on a plurality of information handling systems 100.

The information handling system 100 may include the hardware processor 102 such as a central processing unit (CPU). Any of the processing resources may operate to execute code that is either firmware or software code. Moreover, the information handling system 100 may include memory such as main memory 108, static memory 110, and disk drive unit 122 (volatile (e.g., random-access memory, etc.), nonvolatile memory (read-only memory, flash memory etc.) or any combination thereof or other memory with computer readable medium 112 storing instructions (e.g., software algorithms), parameters, and profiles 114 executable by the hardware processor 102, EC 104, GPU 106, or any other hardware processing device. The information handling system 100 may also include one or more buses 120 operable to transmit communications between the various hardware components such as any combination of various I/O devices 144 as well as between hardware processors 102, an EC 104, the operating system (OS) 118, the basic input/output system (BIOS) 116, the wireless interface adapter 130, or a radio module, among other components described herein. In an embodiment, the hardware processor 102, EC 104, and/or GPU 106 may execute one or more bus drivers 172 in order to transmit this data between the information handling system 100 and the input/output devices 144 described herein. In an embodiment, the information handling system 100 may be in wired or wireless communication with the I/O devices 144 such as a headset microphone system 158, speaker 182, a docking station 156, a keyboard 148, a mouse 154, video display device 146, stylus 150, or trackpad 152 among other peripheral devices.

As described herein, the information handling system 100 further includes a video/graphics display device 146. The video/graphics display device 146 in an embodiment may function as a liquid crystal display (LCD), an organic light emitting diode (OLED), a flat panel display, or a solid-state display. It is appreciated that the video/graphics display device 146 may be wired or wireless and may be an external video/graphics display device 146 that allows a user to increase the desktop area by extending the desktop in an embodiment. Additionally, as described herein, the information handling system 100 may include or be operatively coupled to one or more other I/O devices 144 including the headset microphone system 158 with its first microphone 160, second microphone 168, and one or more speakers 182 described in example embodiments herein that allows the user to interface with the information handling system 100 via the video/graphics display device 146, a cursor control device (e.g., a trackpad 152, or gesture or touch screen input), a stylus 150, and/or a keyboard 148, among others. Information handling system 100 may also be operatively coupled to a peripheral device 144 such as a docking station 156 or other smart peripheral device having a hardware processing device such as a hardware processor, microcontroller, or other hardware processing resource and which may be further operatively coupled to one or more additional peripheral devices 144. Various drivers and hardware control device electronics may be operatively coupled to operate the I/O devices 144 according to the embodiments described herein. The present specification contemplates that any of the I/O devices 144 may be wired or wireless.

A network interface device of the information handling system 100 shown as wireless interface adapter 130 can provide connectivity among devices such as with Bluetooth® or to a network 138, e.g., a wide area network (WAN), a local area network (LAN), wireless local area network (WLAN), a wireless personal area network (WPAN), a wireless wide area network (WWAN), or other network. In embodiments described herein, the wireless interface device 130 with its radio 132, RF front end 134 and antenna 136 is used to communicate with the wireless peripheral devices such as the headset microphone system 158 via, for example, a Bluetooth® or Bluetooth® Low Energy (BLE) protocols. In an embodiment, the WAN, WWAN, LAN, and WLAN may each include an AP 140 or base station 142 used to operatively couple the information handling system 100 to a network 138. In a specific embodiment, the network 138 may include macro-cellular connections via one or more base stations 142 or a wireless AP 140 (e.g., Wi-Fi), or such as through licensed or unlicensed WWAN small cell base stations 142. Connectivity may be via wired or wireless connection. For example, wireless network wireless APs 140 or base stations 142 may be operatively connected to the information handling system 100. Wireless interface adapter 130 may include one or more radio frequency (RF) subsystems (e.g., radio 132) with transmitter/receiver circuitry, modem circuitry, one or more antenna radio frequency (RF) front end circuits 134, one or more wireless controller circuits, amplifiers, antennas 136 and other circuitry of the radio 132 such as one or more antenna ports used for wireless communications via multiple radio access technologies (RATs). The radio 132 may communicate with one or more wireless technology protocols.

In an embodiment, the wireless interface adapter 130 may operate in accordance with any wireless data communication standards. To communicate with a wireless local area network, standards including IEEE 802.11 WLAN standards (e.g., IEEE 802.11ax-2021 (Wi-Fi 6E, 6 GHz)), IEEE 802.15 WPAN standards, WWAN such as 3GPP or 3GPP2, Bluetooth® standards, or similar wireless standards may be used. Wireless interface adapter 128 may connect to any combination of macro-cellular wireless connections including 2G, 2.5G, 3G, 4G, 5G or the like from one or more service providers. Utilization of radio frequency communication bands according to several example embodiments of the present disclosure may include bands used with the WLAN standards and WWAN carriers which may operate in both licensed and unlicensed spectrums. The wireless interface adapter 130 can represent an add-in card, wireless network interface module that is integrated with a main board of the information handling system 100 or integrated with another wireless network interface capability, or any combination thereof.

In some embodiments, software, firmware, dedicated hardware implementations such as application specific integrated circuits, programmable logic arrays and other hardware devices may be constructed to implement one or more of some systems and methods described herein. Applications that may include the apparatus and systems of various embodiments may broadly include a variety of electronic and computer systems. One or more embodiments described herein may implement functions using two or more specific interconnected hardware modules or devices with related control and data signals that may be communicated between and through the modules, or as portions of an application-specific integrated circuit. Accordingly, the present system encompasses software, firmware, and hardware implementations.

In accordance with various embodiments of the present disclosure, the methods described herein may be implemented by firmware or software programs executable by a hardware controller or a hardware processor system. Further, in an exemplary, non-limited embodiment, implementations may include distributed hardware processing, component/object distributed hardware processing, and parallel hardware processing. Alternatively, virtual computer system processing may be constructed to implement one or more of the methods or functionalities as described herein.

The present disclosure contemplates a computer-readable medium that includes instructions, parameters, and profiles 114 or receives and executes instructions, parameters, and profiles 114 responsive to a propagated signal, so that a hardware device connected to a network 138 may communicate voice, video, or data over the network 138. Further, the instructions 114 may be transmitted or received over the network 138 via the network interface device or wireless interface adapter 130. It is appreciated that any computing device including the cloud orchestrator server 160, the cloud orchestrator console 178, and the information handling system 100 may include a computer-readable medium that includes instructions, parameters, and profiles 114.

The information handling system 100 may include a set of instructions 114 that may be executed to cause the computer system to perform any one or more of the methods or computer-based functions disclosed herein. For example, instructions 114 may be executed by a hardware processor 102, GPU 106, EC 104 or any other hardware processing resource and may include software agents, or other aspects or components used to execute the methods and systems described herein. Various software modules comprising application instructions 114 may be coordinated by an OS 118, and/or via an application programming interface (API) include a unified device API described herein. An example OS 118 may include Windows®, Android @, and other OS types. Example APIs may include Win 32, Core Java API, or Android APIs.

In an embodiment, the information handling system 100 may include a disk drive unit 122. The disk drive unit 122 and may include machine-readable code instructions, parameters, and profiles 114 in which one or more sets of machine-readable code instructions, parameters, and profiles 114 such as firmware or software can be embedded to be executed by the hardware processor 102 or other hardware processing devices such as a GPU 106 or EC 104, or other microcontroller unit to perform the processes described herein. Similarly, main memory 108 and static memory 110 may also contain a computer-readable medium for storage of one or more sets of machine-readable code instructions, parameters, or profiles 114 described herein. The disk drive unit 122 or static memory 110 also contain space for data storage. Further, the machine-readable code instructions, parameters, and profiles 114 may embody one or more of the methods as described herein. In a particular embodiment, the machine-readable code instructions, parameters, and profiles 114 may reside completely, or at least partially, within the main memory 108, the static memory 110, and/or within the disk drive 122 during execution by the hardware processor 102, EC 104, or GPU 106 of information handling system 100.

Main memory 108 or other memory of the embodiments described herein may contain computer-readable medium (not shown), such as RAM in an example embodiment. An example of main memory 108 includes random access memory (RAM) such as static RAM (SRAM), dynamic RAM (DRAM), non-volatile RAM (NV-RAM), or the like, read only memory (ROM), another type of memory, or a combination thereof. Static memory 110 may contain computer-readable medium (not shown), such as NOR or NAND flash memory in some example embodiments. The applications and associated APIs, for example, may be stored in static memory 110 or on the disk drive unit 122 that may include access to a machine-readable code instructions, parameters, and profiles 114 such as a magnetic disk or flash memory in an example embodiment. While the computer-readable medium is shown to be a single medium, the term “computer-readable medium” includes a single medium or multiple media, such as a centralized or distributed database, and/or associated caches and servers that store one or more sets of machine-readable code instructions. The term “computer-readable medium” shall also include any medium that is capable of storing, encoding, or carrying a set of machine-readable code instructions for execution by a processor or that cause a computer system to perform any one or more of the methods or operations disclosed herein.

In an embodiment, the information handling system 100 may further include a power management unit (PMU) 124 (a.k.a. a power supply unit (PSU)). The PMU 124 may include a hardware controller and executable machine-readable code instructions to manage the power provided to the components of the information handling system 100 such as the hardware processor 102 and other hardware components described herein. The PMU 124 may control power to one or more components including the one or more drive units 122, the hardware processor 102 (e.g., CPU), the EC 104, the GPU 106, a video/graphic display device 146, or other wired I/O devices 144 such as the mouse 154, the stylus 150, the keyboard 148, the headset microphone system 158 with its first microphone 160 and second microphone 168, the speaker 182, and the trackpad 152 and other components that may require power when a power button has been actuated by a user. In an embodiment, the PMU 124 may monitor power levels and be electrically coupled to the information handling system 100 to provide this power. The PMU 124 may be coupled to the bus 120 to provide or receive data or machine-readable code instructions. The PMU 124 may regulate power from a power source such as the battery 126 or AC power adapter 128. In an embodiment, the battery 126 may be charged via the AC power adapter 128 and provide power to the components of the information handling system 100, via wired connections as applicable, or when AC power from the AC power adapter 128 is removed.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes or other storage device to store information received via carrier wave signals such as a signal communicated over a transmission medium. Furthermore, a computer readable medium 110 can store information received from distributed network resources such as from a cloud-based environment. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or machine-readable code instructions may be stored.

In other embodiments, dedicated hardware implementations such as application specific integrated circuits (ASICs), programmable logic arrays and other hardware devices can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses hardware resources executing software or firmware, as well as hardware implementations.

As described herein, the information handling system 100 is operatively coupled to a headset microphone system 158 via wired or wireless operatively coupling. In another embodiment, the first microphone 160, second microphone 168, and one or more speakers 182 of the microphone system 158 may form part of the information handling system 100. In this embodiment, the first microphone 160, second microphone 168, and one or more speakers 182 may be formed into a housing of the information handling system such as a microphone system 158 associated with a webcam used by a user to engage in, for example, a videoconferencing session. In another embodiment, the headset microphone system 158 with its first microphone 160, second microphone 168, and one or more speakers 182 may form part of its own input/output device 144 and may be operatively coupled to the information handling system via a wired connection such as via a universal serial bus (USB) connection. In yet another embodiment, the headset microphone system 158 may form part of its own input/output device 144 and may be wirelessly coupled with the information handling system via the wireless interface adapter 130 via Bluetooth® (BT) or Bluetooth® Low Energy (BLE) connection. In these embodiments, the headset microphone system 158 may form part of a headset that a user may wear in order to receive audio output via a speaker or speakers 182 from the information handling system 100 and provide input to the information handling system 100 via the first microphone 160 and second microphone 168 of the headset microphone system 158.

In an embodiment, the headset microphone system 158 includes a first microphone 160 to capture audio input from a user as well as a second microphone 168 to also capture audio input from a user. In an embodiment, the first microphone 160 and second microphone 168 may have diverse characteristics such that the first microphone 160 and second microphone 168 may operate together in order to increase the dynamic range control (DRC) and signal-to-noise ratio (SNR) across a wider range of audio input levels of the headset microphone system 158. Additionally, the characteristics of the first microphone 160 and second microphone 168 may be diverse such that distortion at the headset microphone system 158 is minimized and lower floor noise level is realized. Thus, the systems and methods described herein increases the speech input range detectable by the headset microphone system 158 through the use of a digital signal processor 162 on the headset microphone system 158 executing computer-readable program code of a low and high threshold detection module 174 and dual microphone audio mixing module 176 as described herein thereby increasing user satisfaction during operation of the headset microphone system 158.

The headset microphone system 158 may include a digital signal processor 162 that executes computer-readable program code that splits the audio output into three speech ranges. A first speech range may include a speech range detectable by the first microphone 160. A second speech range may include a speech range detectable by the second microphone 168. A third speech range may include an overlap speech range detectable by both the first microphone 160 and second microphone 168 and mixed to form this third speech range. In order to accomplish this, a digital signal processor 162 of the headset microphone system 158 may execute computer-readable program code of a dual microphone audio mixing module 176 in order to mix input from each of the first microphone and second microphone when the audio detected at the first microphone exceeds a low decibel range threshold and the audio detected at the second microphone falls below a high decibel range threshold.

During operation, the user may provide audio input at the first microphone 160 and second microphone 168 of the headset microphone system 158. By way of example, the first microphone 160 may have a microphone sensitivity level upper level at −26 decibels per pascals (dbV/Pa), an SNR of 70 dB, and an acoustic overload point (AOP) of 110 dB. In this example embodiment, the second microphone 168 may have a microphone sensitivity level upper level at −56 dbV/Pa, an SNR of 45 dB, and an AOP of 140 dB. It is appreciated that any two microphones may be used in the present specification with each of the microphones having different sensitivity levels, SNRs, and AOP sufficient to provide a wider speech input range than just one microphone as described herein. In an embodiment, the audio input at the first microphone 160 may be passed through a high gain amplifier operatively coupled to the first microphone 160 to increase the amplitude of the signal received at the first microphone 160. Additionally, a first dynamic range controller (DRC) 166 may be operatively coupled to the high gain amplifier to set the low decibel range threshold for the first microphone. In an embodiment, this low decibel range threshold associated with the first microphone 160 may be set to 70 db. Still further, a low gain amplifier 170 may be coupled to the second microphone 168 to increase the amplitude of the signal received at the second microphone 168. In this embodiment, a second DRC 172 may be operatively coupled to the low gain amplifier 170 to set the high decibel range threshold for the second microphone 168. In an embodiment, this high decibel range threshold may be set to 90 dB.

As the audio is input into the first microphone 160 and second microphone 168, the digital signal processor 162 may execute computer-readable program code of a low and high threshold detection module 174. The execution of the low and high threshold detection module 174 allows the digital signal processor 162 to determine when the audio input at the first microphone 160 exceeds the low decibel range threshold (e.g., 70 dB). The execution of the low and high threshold detection module 174 allows the digital signal processor 162 to also determine when the audio input at the second microphone 168 falls below the high decibel range threshold (e.g., 90 dB). The audio input at the first microphone 160 that does not exceed the low decibel range threshold (e.g., 70 dB) or falls below this low decibel range threshold is then passed from the first microphone 160 onto an anti-echo cancelation and noise reduction module (AEC/NR) 178 for further processing by the digital signal processor 162. Similarly, the audio input at the second microphone 168 that does not fall below the high decibel range threshold (e.g., 90 dB) or is above the second high decibel range threshold is then passed from the second microphone 168 onto the AEC/NR module 178 for further processing as described herein. However, when audio input from the first microphone 160 exceeds the low decibel range threshold (e.g., 70 dB), it is passed onto a dual microphone audio mixing module 176 of the digital signal processor 162 to be mixed with audio input from the second microphone 168. Still further, when that same audio input from the second microphone 168 also falls below the high decibel range threshold (e.g., 90 dB) the audio input from the second microphone 168 is also passed onto the dual microphone audio mixing module 176 to be mixed with the audio input from the first microphone 160.

As described herein, the digital signal processor 162 may execute the computer-readable program code of the dual microphone audio mixing module 176 to mix that audio input from the first microphone 160 that exceeds the low decibel range threshold (e.g., 70 dB) with the audio input from the second microphone 168 that falls below the high decibel range threshold (e.g., 90 dB) or in between the low decibel range threshold and the high decibel range threshold. Thus, the audio input provided at the first microphone 160 and second microphone 168 may fall into one of three categories, namely, audio that falls below the low decibel range threshold (e.g., 70 dB) at the first microphone 160, audio that exceeds the high decibel range threshold (e.g., 90 dB) at the second microphone 168, or audio from both the first microphone 160 and second microphone 168 that falls within the decibel range defined by the low decibel range threshold (e.g., 70 dB) and high decibel range threshold (e.g., 90 dB). This allows, for example, the first microphone 160 to detect speech input at a relatively lower decibel level floor (i.e., soft speech) while the second microphone 168 may also detect speech input at a relatively high input level (i.e., loud speech, shouting) thereby increasing the range of speech input that is detectable by the headset microphone system 158 with two microphones 160 and 168. This calibrated dual microphone audio mixing module 176, therefore, manages the coverage of both the first microphone 160 and second microphone 168 by considering SNRs, sensitivity levels, and AOP. Speech input levels in between the low decibel range threshold (e.g., 70 dB) and the high decibel range threshold (e.g., 90 dB) are calibrated and mixed based on the SNR and sensitivity levels of both the first microphone 160 and second microphone 168. In an embodiment, the execution of the computer-readable program code of the dual microphone audio mixing module 176 by the digital signal processor 162 extends the output level at the floor and ceiling speech levels thereby increasing the speech range detectable by the headset microphone system 158. This increases the audio detection capabilities of the headset microphone system 158 as well as increases the user satisfaction during operation of the information handling system.

The digital signal processor 162 may also execute computer-readable program code of an anti-echo cancellation and noise reduction (AEC/NR) module 178 as described herein. In an embodiment, that audio data that may be passed through the low and high threshold detection module 174 and dual microphone audio mixing module 176 where applicable as well as single audio streams from either microphone 160 or 168 individually where application are further processed via this execution of the AEC/NR module 178. In an embodiment, the AEC/NR module 178 processes the received audio to reduce echo and noise present in the audio stream from the first microphone and second microphone. It is appreciated that any algorithm may be used to reduce the echo and noise present in the audio to increase the sound quality prior to output to a speaker 182 for example. For example, an anti-echo cancellation algorithm may include a finite impulse response algorithm and a Kalman filter algorithm as well as neural networks that have been trained to estimate spatial magnitude masks. Example noise reduction algorithms may include wiener filtering algorithms, local signal-and-noise orthogonalization algorithm, and neural networks. These algorithms may be combined to reduce the echo and noise present in the audio to increase the sound quality prior to output to a speaker 182.

In an embodiment, the digital signal processor 162 may further execute computer-readable program code of an automatic gain control (AGC) module 180. Execution of the computer-readable program code of the AGC module 180 causes the audio to be further processed to maintain a signal output from the AEC/NR module 178 to the speaker 182 operatively coupled to the information handling system. In an embodiment, the AGC module 180 may adjust the power or amplitude of the audio signal that has, by the execution of the AEC/NR module 178, relatively low echo and noise.

The audio signal output from the digital signal processor 162 may then be sent to a speaker 182 as output from the information handling system 100. In an embodiment, the speaker 182 may be formed into an information handling system remote from the information handling system 100 shown in FIG. 1 and used by another user during, for example, a videoconferencing session or gaming session. In an alternative embodiment, the speaker 182 may form part of a headset worn by a user remote from the information handling system 100 and engaging, in real-time, with the user via a remote information handling system.

In an embodiment, the headset microphone system 158 may include a microphone system PMU 184. The microphone system PMU 184 may include a hardware controller and executable machine-readable code instructions to manage the power provided to the components of the headset microphone system 158 such as the digital signal processor 162 and other hardware components described herein. In an embodiment, the microphone system PMU 184 may monitor power levels and, in the context of the headset microphone system 158 being present on a headset, provide power to those components of the headset including a speaker 182. In an embodiment, the microphone system PMU 184 may regulate power from a power source such as the microphone system battery 186 or a microphone system A/C power adapter 188. In an embodiment, the microphone system battery 186 may be charged via the microphone system A/C power adapter 188 and provide power to the headset microphone system 158 via wired connections as applicable, or when AC power from the microphone system A/C power adapter 188 is removed.

When referred to as a “system,” a “device,” a “module,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device). The system, device, controller, or module can include hardware processing resources executing software, including firmware embedded at a device, such as an Intel® brand processor, AMD® brand processors, Qualcomm® brand processors, or other processors and chipsets, or other such hardware device capable of operating a relevant software environment of the information handling system. The system, device, controller, or module can also include a combination of the foregoing examples of hardware or hardware executing software or firmware. Note that an information handling system can include an integrated circuit or a board-level product having portions thereof that can also be any combination of hardware and hardware executing software. Devices, modules, hardware resources, or hardware controllers that are in communication with one another need not be in continuous communication with each other, unless expressly specified otherwise. In addition, devices, modules, hardware resources, and hardware controllers that are in communication with one another can communicate directly or indirectly through one or more intermediaries.

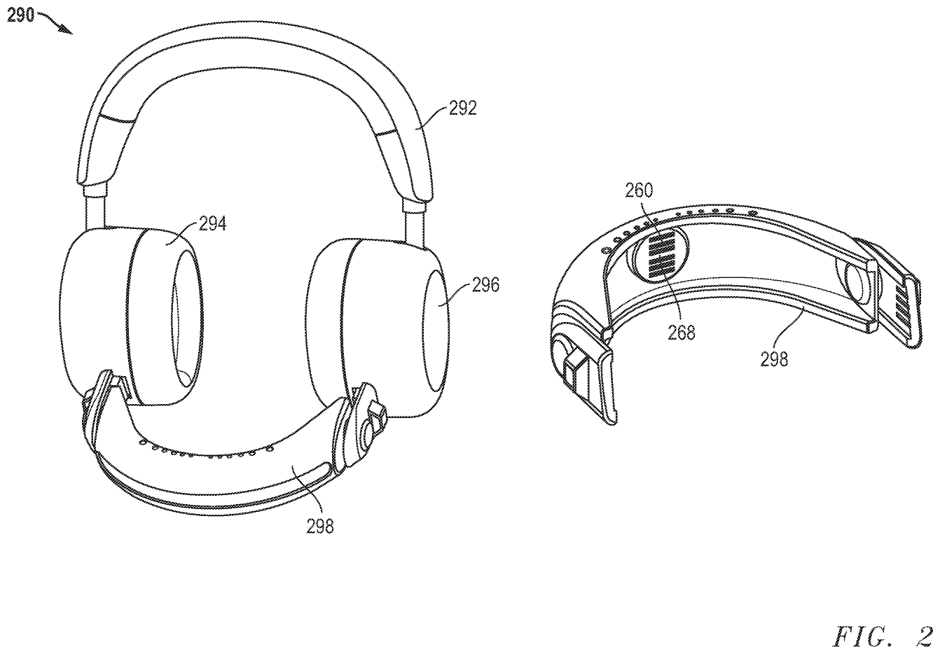

FIG. 2 is a diagram depicting a headset 290 that includes dual microphones 260, 268 used to increase speech range according to an embodiment of the present disclosure. As described herein, the headset 290 may be an input/output device that is operatively coupled to an information handling system such as that described in connection with FIG. 1. The operative connection may be via a wired connection or a wireless connection.

The headset 290 may include a headband 292 that, when worn by a user, rests on the user' head. The headband 292 is also operatively coupled to a first earpiece 294 with a first speaker at a first end of the headband 292 and a second earpiece 296 with a second speaker at a second end of the headband 292. This allows the first earpiece 294 to be placed over or at a first ear of the user and the second earpiece 296 over or at a second ear of the user. In an embodiment, both the first earpiece 294 and second earpiece 296 may include a speaker or other audio output device that allows a user to hear an audio signal.

In an embodiment, the headset 290 may also include a mouthpiece or microphone boom 298. The mouthpiece or microphone boom 298 may be any type of device that includes the first microphone 260 and second microphone 268 described herein. In the example embodiment shown in FIG. 2, the mouthpiece or microphone boom 298 includes at least a first end that may be operatively and selectively coupled to the headset 290 at a first earpiece 294. A second end of the mouthpiece or microphone boom 298 may be operatively coupled to the headset 290 at a second earpiece 296 in some embodiments. It is appreciated that the mouthpiece or microphone boom 298 extends out from either of the second earpiece 296 or first earpiece 294 or both and allows microphone boom to be placed in front of the user's mouth so as to place the first microphone 260 and second microphone 268 at a location where audio input from the user's mouth may be received at both the first microphone 260 and second microphone 268 as described herein.

Again, the headset 290 may include a headset microphone system such as that described in connection with FIG. 1 (e.g., 158, FIG. 1). In an embodiment, the first microphone 260 and second microphone 268 of the headset microphone system may form part of the headset 290 and may include any circuitry include a digital signal microprocessor or other hardware processing resource that is formed into one or both of the first earpiece 294 and second earpiece 296 for example. In this embodiment, the first microphone 260 and second microphone 268 may be formed into a housing of the mouthpiece or microphone boom 298. In this embodiment shown in FIG. 2, the headset microphone system may form part of a headset 290 that a user may wear in order to receive audio output from the information handling system (e.g., generated at the information handling system or at an information handling system remote from the user's information handling system) and provide audio input to the information handling system via the first microphone 260 and second microphone 268 of the headset microphone system.

As described, the headset microphone system includes a first microphone 260 to capture audio input in a first audio input stream from a user and a second microphone 268 to capture a second audio input stream from a user at the same time. In an embodiment, the first microphone 260 and second microphone 268 may have diverse characteristics such that the first microphone 260 and second microphone 268 may operate together in order to increase the DRC and SNR for a wider range of the headset microphone system. Additionally, the characteristics of the first microphone 260 and second microphone 268 may be diverse such that distortion at the headset microphone system is minimized and lower floor noise is realized to allow a wider decibel range to be captured without distortion or clipping. Thus, the systems and methods described herein increases the speech input range detectable and the quality of that speech input range for the headset microphone system through the use of a digital signal processor executing computer-readable program code of a low and high threshold detection module and dual microphone audio mixing module as described in FIG. 1 thereby increasing user satisfaction during operation of the headset microphone system.

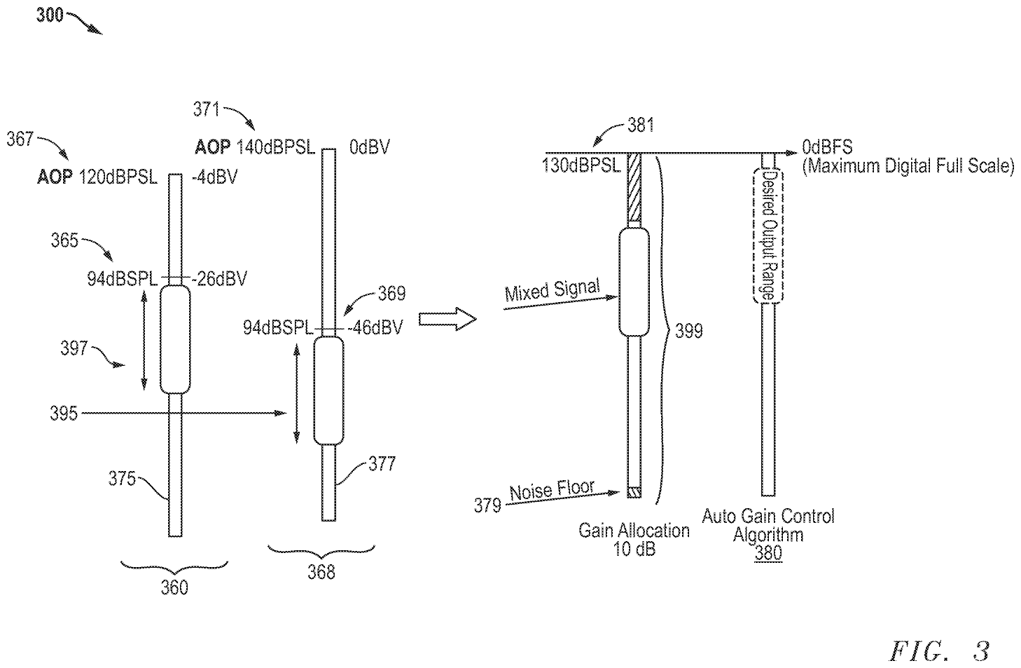

FIG. 3 is a diagram depicting speech ranges of a dual headset microphone system including a speech range of a first microphone 360 and a second speech range of a second microphone 368 and showing the resulting increase in speech output range 399 according to an embodiment of the present disclosure. As described herein, the first microphone 360 and second microphone 368 may have different characteristics that allow for the systems and methods described herein to increase the range and quality in that range of detectable speech from a user.

During operation, the user may provide audio input at the first microphone 360 and second microphone 368 of the headset microphone system. By way of example, the first microphone 360 may have a first output range 375, a first microphone sensitivity level 365 at an upper level of −26 dbV/Pa that is equivalent to about 94 dB sound pressure level (SPL), an SNR of 70 dB, and a first microphone AOP 367 of 120 dB. In this example embodiment, the second microphone 368 may have a second output range 377, a second microphone sensitivity level 369 at an upper level of −46 dbV/Pa that is equivalent to about 94dBSPL, an SNR of 45 dB, and a second microphone AOP 371 of 140 dB. In this embodiment, the first microphone 360 may have a first normal speech detection range 397 that is a higher decibel range than that of the second microphone's 368 second normal speech detection range 395 but that also overlaps the second normal speech detection range 395 thus expanding the detected decibel range of capture user speech input. It is appreciated that any two microphones may be used in the present specification with each of the microphones having different sensitivity levels 365, 369, SNRs, and AOPs 367, 371 sufficient to provide a wider speech input range as described herein. In an embodiment, the execution of the computer-readable program code of the low and high threshold detection module and dual microphone audio mixing module described herein increases the detectable speech output range of the first microphone 360 and second microphone 368 resulting in a combined speech detectable speech output range 399.

As the audio is input into the first microphone 360 and second microphone 368, the digital signal processor of the headset microphone system may execute computer-readable program code of the low and high threshold detection module. The execution of the low and high threshold detection module allows the digital signal processor to determine when the audio input at the first microphone 360 exceeds or falls below the low decibel range threshold (e.g., 70 dB). The execution of the low and high threshold detection module allows the digital signal processor to also determine when the audio input at the second microphone 368 exceeds or falls below the high decibel range threshold (e.g., 90 dB). When the first audio input stream at the first microphone 360 does not exceed and instead falls below the low decibel range threshold (e.g., 70 dB) then the first audio input stream from the first microphone 360 is passed onto an AEC/NR module for further processing by the digital signal processor. Similarly, when the second audio input stream at the second microphone 368 that does not fall below and instead exceeds the high decibel range threshold (e.g., 90 dB), the second audio input stream from the second microphone 368 is passed onto the AEC/NR module for further processing as described herein. However, when first audio input stream from the first microphone 360 exceeds the low decibel range threshold (e.g., 70 dB) and the second audio input stream from the second microphone 368 falls below the high decibel range threshold (e.g., 90 dB), then both the first audio input stream and the second audio input stream are also passed from the first microphone 360 and the second microphone 368 to the dual microphone audio mixing module.

As described herein, the digital signal processor may execute the computer-readable program code of the dual microphone audio mixing module to mix that first audio input stream from the first microphone 360 that exceeds the low decibel range threshold (e.g., 70 dB) with the second audio input stream from the second microphone 368 that falls below the high decibel range threshold (e.g., 90 dB). Thus, the audio input provided at the first microphone 360 and second microphone 368 may fall into one of three categories, namely, audio that falls below the low decibel range threshold (e.g., 70 dB) at the first microphone 360, audio that exceeds the high decibel range threshold (e.g., 90 dB) at the second microphone 368, and audio from both the first microphone 360 and second microphone 368 that falls within the decibel range defined by the low decibel range threshold (e.g., 70 dB) and high decibel range threshold (e.g., 90 dB). This allows, for example, the first microphone 360 to detect speech input at a relatively lower noise floor 379 such as quiet speech from the user while the second microphone 368 may also detect speech input at a relatively high input level such as loud speech from the user thereby increasing the range of speech input that is detectable and the quality within that range as detected by the dual microphone headset microphone system. This calibrated dual microphone audio mixing module, therefore, manages the coverage of both the first microphone 360 and second microphone 368 having wider coverage for SNRs, sensitivity levels, and AOP at different speech decibel levels while avoiding distortion due to gain and downstream signal processing that would occur with a single microphone with limited audio characteristics. This increases the range and quality of the detectable speech levels from the user. For speech input levels in between the low decibel range threshold (e.g., 70 dB) and the high decibel range threshold (e.g., 90 dB), these are calibrated and mixed based on the SNR and sensitivity levels of both the first microphone 360 and second microphone 368. In an embodiment, the execution of the computer-readable program code of the dual microphone audio mixing module by the digital signal processor extends the output level at the floor and ceiling speech levels while minimizing distortion due to gain, noise reduction or echo-cancellation that might otherwise occur with just one microphone at the edges of the speech range. This increases the effective speech range detectable by the headset microphone system as indicated by the resulting speech output range 399 in FIG. 3. Additionally, a maximum resulting AOP 381 may be set to prevent hearing damage to the user wearing a headset remote from the information handling system or speaker damage at that remote information handling system. The systems and methods described herein increases the audio detection capabilities of the headset microphone system as well as increases the user satisfaction during operation of the information handling system.

In an embodiment, an AGC module (e.g., FIG. 1, 180) may, via execution of an auto gain control algorithm 380, adjust the power or amplitude of the audio signal that has, by the execution of AEC/NR module (e.g., FIG. 1, 178), relatively low echo and noise resulting in an appropriate desired decibel output range for the user. It is appreciated that any further digital signal processing may be applied to the audio streams from the first microphone 360, the second microphone 368, or a mixed signal that would improve the quality of the audio presented to the user at a speaker or at the headsets described herein. As a result, the first microphone 360 and second microphone 368 serve as a low decibel range (e.g., via the first microphone 360) and a relatively high decibel range (e.g., via the second microphone 368) in order to cover a bigger decibel range without gain limits and a resulting distortion due to upstream signal processing. This is in contrast to a single microphone where the single microphone would have physical and signal processing limits that would cause such distortion when, for example, a user speaks too loudly or softly during use.

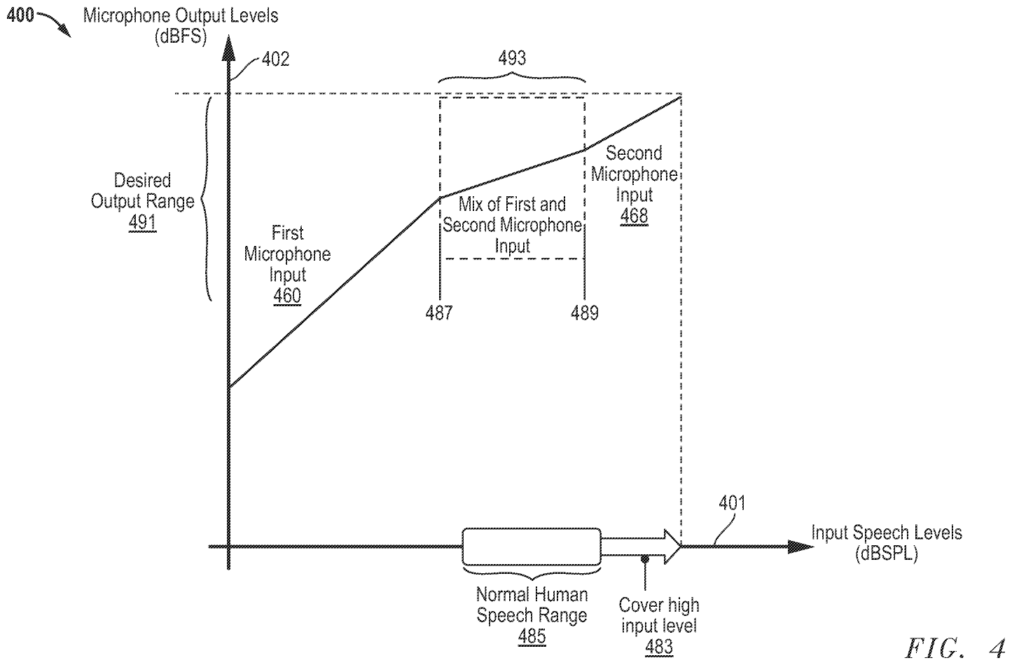

FIG. 4 is a graph 400 showing voice input 401 to and resulting output 402 from a first microphone 460, a second microphone 468, and a mixed range 493 from the inputs of the first microphone 460 and second microphone 468 of a headset microphone system where audio from each microphone 460, 468 is mixed via execution of a dual microphone audio mixing module according to one or more embodiments of the present disclosure. As described herein, the output levels of the first microphone 460, the output levels of the second microphone 468, and the mixed output levels 493 of the first microphone 460 and second microphone 468 are plotted on the graph 400. The graph 400 shows the relationship between the voice input levels 401 (decibel sound pressure level, dBSPL) and the microphone output levels 402 (in decibel volts; dBV) for each of the first microphone 460 and second microphone 468 thereby illustrating the changes in microphone output levels 402 across the voice input range 401.

The graph 400 shows that a normal human speech range 485 plotted on the lower axis of voice input range 401 in the graph 400 and that may fall wholly or partially within the mixed range 493. Additionally, higher input levels 483 may also fall above the mixed range 493 and be covered only by the second microphone voice input 468. Lower voice input levels 481 may fall below the mixed range 493 or partially in the mixed range 493 such that the mixed range 493 or just the first microphone voice input 460 will cover this. A desired microphone output range 491 for overall decibel capability of the headset microphone system is also indicated on the vertical axis microphone output 402 of the graph 400 that indicates desired microphone decibel output levels of the headset microphone system described herein that may not be available with just one microphone.

During operation, the user may provide voice audio input at the first microphone and second microphone of the headset microphone system. By way of example, the first microphone 460 may have a microphone sensitivity level upper level at −26 decibels per pascals (dbV/Pa), an SNR of 70 dB, and an acoustic overload point (AOP) of 110 dB. In this example embodiment, the second microphone 468 may have a microphone sensitivity level upper level at −56 dbV/Pa, an SNR of 45 dB, and an AOP of 140 dB. As the voice audio is input into the first microphone and second microphone, the digital signal processor may execute computer-readable program code of a low and high threshold detection module. The execution of the low and high threshold detection module allows the digital signal processor to determine when the first audio input stream at the first microphone 460 falls below or exceeds the low decibel range threshold 487 (e.g., 70 dB). The execution of the low and high threshold detection module allows the digital signal processor to also determine when the second audio input stream at the second microphone falls below or exceeds the high decibel range threshold 489 (e.g., 90 dB). In an embodiment, the execution of the low and high threshold detection module may therefore set the mixed range 493 as between low decibel range threshold 487 and high decibel range threshold 489 described herein. Thus, when the first audio input stream from the first microphone that exceeds the low decibel range threshold 487 (e.g., 70 dB) and the second audio input stream from the second microphone 468 that falls below the high decibel range threshold 489 (e.g., 90 dB), both data streams are passed onto the dual microphone audio mixing module to be mixed as described herein.

In an embodiment, the voice audio input provide at the first microphone and second microphone may fall into one of three categories, namely, voice audio that falls below the low decibel range threshold 487 (e.g., 70 dB) at the first microphone, voice audio that exceeds the high decibel range threshold 489 (e.g., 90 dB) at the second microphone, and voice audio input streams from both the first microphone and second microphone that falls within the decibel range defined by the low decibel range threshold 487 (e.g., 70 dB) and high decibel range threshold 489 (e.g., 90 dB) that forms the mixed range 493 shown on the graph 400. This allows, for example, the first microphone to detect speech input at a relatively lower floor below the low decibel range threshold 487 while the second microphone may detect speech input at a relatively high input level above the high decibel range threshold 489 thereby increasing the range of speech voice input that is usually detectable by a headset microphone system with only one microphone for example. This calibrated dual microphone audio mixing module, therefore, manages the coverage of both the first microphone and second microphone for accommodating relative SNRs, sensitivity levels, and AOP as well as varied input gain used for the differing first microphone and second microphone voice input ranges to provide greater decibel range of speech voice input coverage without distortion or loss due to upstream or downstream signal processing. For speech input levels in between the low decibel range threshold 487 (e.g., 70 dB) and the high decibel range threshold 489 (e.g., 90 dB) are calibrated and mixed based on the SNR and sensitivity levels of both the first microphone and second microphone. This allows, for example, the first microphone 460 to detect speech input at a relatively lower decibel level floor (i.e., soft speech from the user) while the second microphone 468 may also detect speech input at a relatively high input level (i.e., loud speech, shouting from the user) thereby increasing the range of speech input decibels that are detectable without distortion by the headset microphone system described herein thereby avoiding extended voice signal range shortfalls of a single microphone system. In an embodiment, the execution of the computer-readable program code of the dual microphone audio mixing module by the digital signal processor extends the output level at the floor and ceiling speech levels thereby increasing the speech range detectable for the desired output range 491 the headset microphone system. This increases the audio detection capabilities of the headset microphone system as well as increases the user satisfaction during operation of the information handling system.

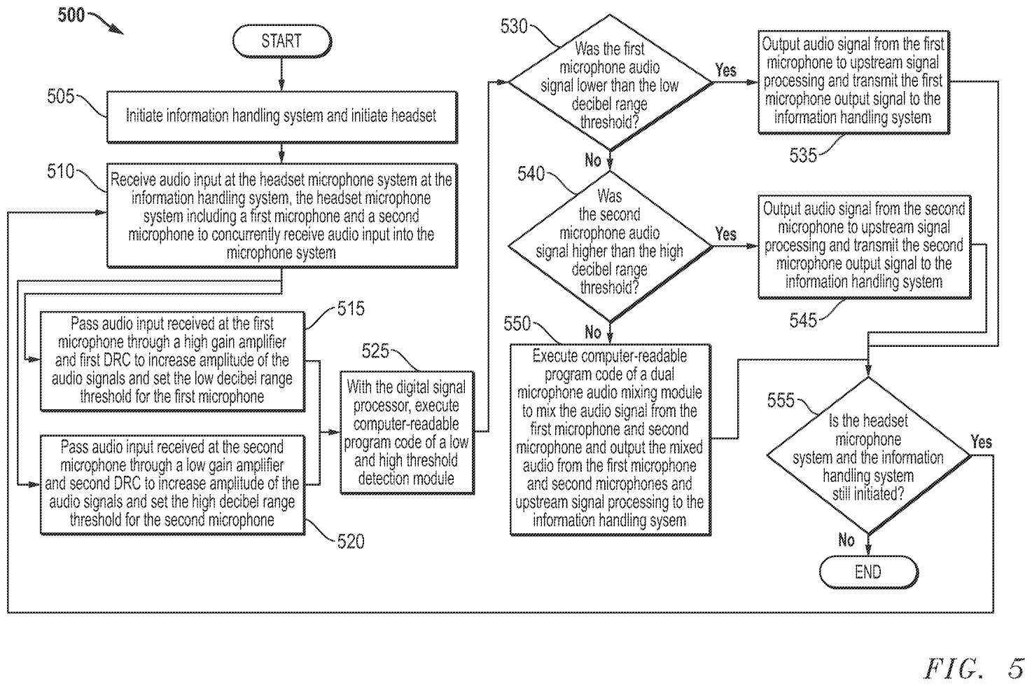

FIG. 5 is a flow chart 500 showing a method of increasing a speech output decibel range of a headset microphone system with limiting distortion according to another embodiment of the present disclosure. In an example, the headset microphone system will be described as being operatively coupled to an information handling system that receives audio input from a user via first microphone and a second microphone at the headset, such as mounted on a boom before the user's mouth, and provides audio output to the information handling system in an extended decibel range for the user while limiting distortion as described herein. This voice audio input may be processed per the operation of the systems and methods described herein in order to provide a headset microphone system that can accept a wider input range with a mixed output range and individual audio stream outputs, where the mixed output range is generated via execution of the low and high threshold detection module and the dual microphone audio mixing module described in embodiments herein.

At block 505, the method 500 may include initiating the information handling system and the headset device. The initiation process of the information handling system may include a user actuating a power button on the information handling system to cause the information handling system to execute computer-readable program code of a BIOS and/or OS to boot up the information handling system. Additionally, the initiation of the headset may include a user actuating a power button on the headset. In an embodiment, the headset microphone system with its first microphone and second microphone may be operatively coupled to the information handling system via a wired connection such as via a universal serial bus (USB) connection. In yet another alternative embodiment, the headset microphone system may be wirelessly coupled with the information handling system via the wireless interface adapter and may form part of an input/output device. The initiation of the headset may be wirelessly paired and also include wirelessly coupling the headset to the information handling system via a BT or BLE wireless connection as described herein when the headset is a wireless headset in embodiments herein.

At block 510, the method 500 may further include receiving audio voice input at a headset microphone system at the information handling system. As described herein, the headset microphone system includes a first microphone and a second microphone situated on a boom in front or otherwise proximate to a user's mouth that concurrently receives the audio voice input from the user. With such a location, a user may speak quietly or may speak loudly or shout in various instances such as when a user uses the same headset device in a gaming context or in a work or teleconference contexts. As such, the boom microphone with a single microphone located near the user's mouth may reach a high decibel saturation and distortion or a low level inability to pick up the voice input or distortion depending on the physical limitations of the microphone, gain used, or any signal processing conducted on the audio signal. In an embodiment, the headset microphone system may use two microphones with differing capabilities at a boom location to form part of a headset device that a user may wear in order to receive audio output from the information handling system at a speaker and provide audio voice input to the information handling system via the first microphone and second microphone of the headset microphone system. In an embodiment, the headset may also include a mouthpiece or microphone boom having the first microphone and second microphone thereon. The mouthpiece or microphone boom may be any type of device that includes the first microphone and second microphone described herein for situating the first microphone and second microphone in front of or otherwise proximate to a user's mouth when the headset device is worn. In an example embodiment, (shown in FIG. 2 for example) the mouthpiece or microphone boom includes at least a first end that may be operatively and selectively coupled to the headset at a first earpiece. A second end of the mouthpiece or microphone boom may be operatively coupled to the headset at a second earpiece in some embodiments. It is appreciated that the mouthpiece or microphone boom extends out from either of the second earpiece or first earpiece and allows microphone boom to be placed in front of the user's mouth so as to place the first microphone and second microphone at a location where audio input from the user's mouth may be received at both the first microphone and second microphone as described herein. The first microphone and second microphone may be located at a similar location on the boom such as vertically adjacent or horizontally adjacent to one another or they may be situated on the boom at a similar distance from the user's mouth when the headset device is worn in various embodiments. In some other embodiments, one microphone have a lower decibel range of operation may be located closer on the boom to the user's mouth than the second microphone having the higher decibel range of operation.

In an embodiment, the first microphone and second microphone may have diverse characteristics such that the first microphone and second microphone may operate together in order to increase the audio output range of the headset microphone system. Additionally, the characteristics of the first microphone and second microphone may be diverse such that distortion at the headset microphone system is minimized and lower floor noise is realized within this wider decibel range of the headset microphone system.

During operation, the user may provide audio input at the first microphone and second microphone of the headset microphone system. By way of example, the first microphone may have a high microphone sensitivity upper level at −26 dbV/Pa, an SNR of 70 dB, and a AOP of 110 dB. In this example embodiment, the second microphone may have a high microphone sensitivity upper level at −56 dbV/Pa, an SNR of 45 dB, and an AOP of 140 dB. It is appreciated that any two microphones may be used in the present specification with each of the microphones having different sensitivity levels, SNRs, and AOP sufficient to provide a wider speech input range while limiting distortion as described herein.

In an embodiment, the audio input at the first microphone may be passed through a high gain amplifier operatively coupled to the first microphone to increase the amplitude of the signal received at the first microphone at block 515. This may be done when the first microphone has a lower decibel range and is designed to capture lower or quieter audio inputs in an embodiment. Additionally, a first DRC may be operatively coupled to the high gain amplifier to set the low decibel range threshold for the first microphone at block 515. In an embodiment, this low decibel range threshold set by the first DRC associated with the first microphone may be set to 70 db.

Still further, a low gain amplifier may be coupled to the second microphone to increase the amplitude of the signal received at the second microphone at block 520, but not as much as the first microphone since the second microphone has a higher decibel range and may accommodate louder voice inputs. A second DRC is operatively coupled to the low gain amplifier, to set the high decibel range threshold for the second microphone. In an embodiment, this high decibel range threshold upper level may be set to 90 dB. The processes associated with blocks 515 and 520 may be part of the preprocessing of the audio signal so that the low decibel range threshold and high decibel range threshold may be set prior to execution of the computer-readable program code of the low and high threshold detection module and the dual microphone audio mixing module as described herein.

At block 525, the digital signal processor of the headset microphone system may execute the computer-readable program code of the low and high threshold detection module to determine whether the detected audio input at the first microphone when the audio input at the first microphone 160 exceeds or falls below the low decibel range threshold (e.g., 70 dB) and when the audio input at the second microphone 168 falls below or exceeds the high decibel range threshold (e.g., 90 dB).

Thus, at block 530, the execution of the low and high threshold detection module may cause the digital signal processor to determine if the audio signal at the first microphone is lower than the low decibel range threshold. Where, at block 530, the audio signal at the first microphone is lower than the low decibel range threshold, the method 500 continues to block 535 with the digital signal processor outputting this audio signal from the first microphone to as audio output to for further signal processing and to the operatively coupled information handling system. It is appreciated that, in some embodiments, further audio processing may be conducted prior to the audio signal from the first microphone being output to the information handling system for transmission or use with software applications. For example, the digital signal processor may also execute computer-readable program code of an AEC/NR module as described herein. In an embodiment, any audio data that is passed by and through the low and high threshold detection module and/or dual microphone audio mixing module is further processed via this execution of the AEC/NR module. In an embodiment, the AEC/NR module processes the received audio to reduce echo and noise present in the audio stream from the first microphone and second microphone. It is appreciated that any algorithm may be used to reduce the echo and noise present in the audio to increase the sound quality prior to output to a speaker for example.

In an embodiment, the digital signal processor may further execute computer-readable program code of an AGC module. Execution of the computer-readable program code of the AGC module causes the audio to be further processed to maintain a signal output from the AEC/NR module to the speaker operatively coupled to the information handling system. In an embodiment, the AGC module may adjust the power or amplitude of the audio signal that has, by the execution of the AEC/NR module, relatively low echo and noise. The audio signal output from the digital signal processor may then be sent to a speaker as output from the information handling system.

Where, at block 530, the audio signal from the first microphone is not lower than the low decibel range threshold, the execution of the computer-readable program code of the low and high threshold detection module may further determine, at block 540, whether the audio signal from the second microphone is higher than the high decibel range threshold. Where the audio signal from the second microphone is higher than the high decibel range threshold at block 540, the method 500 may, at block 545 provide the audio signal from the second microphone to the information handling system as audio output. Again, other audio processing may be conducted prior to the output being provided to the information handling system and on to a remote speaker or used with software applications. This other audio processing may again include execution of the computer-readable program code of the AEC/NR module and AGC module as described herein in order to mitigate or eliminate echo and noise within the audio signal from the second microphone as well as adjust the power or amplitude of the audio signal where necessary.

Where, at block 540, the second microphone audio signal is not higher than the high decibel range threshold, the method 500 proceeds to block 550. At block 550 the digital signal processor may execute computer-readable program code of the dual microphone audio mixing module to mix the audio signal from the first microphone and the audio signal from the second microphone in order to output a mixed audio signal to the speaker. As described herein, the digital signal processor may execute the computer-readable program code of the dual microphone audio mixing module to mix that audio input from the first microphone that exceeds the low decibel range threshold (e.g., 70 dB) with the audio input from the second microphone that falls below the high decibel range threshold (e.g., 90 dB). Again, other audio processing may be conducted prior to the output being provided to the information handling system and on to a remote speaker or used with software applications as described in embodiments herein.

Thus, the audio input provided at the first microphone and second microphone may fall into one of three categories, namely, audio that falls below the low decibel range threshold (e.g., 70 dB) at the first microphone, audio that exceeds the high decibel range threshold (e.g., 90 dB) at the second microphone, or audio from both the first microphone and second microphone that falls within the decibel range defined by the low decibel range threshold (e.g., 70 dB) and high decibel range threshold (e.g., 90 dB). This allows, for example, the first microphone to detect speech input at a relatively lower decibel level floor (i.e., soft speech) while the second microphone may also detect speech input at a relatively high input level (i.e., loud speech, shouting) thereby increasing the range of speech input that is detectable while limiting distortion due to gain and additional digital processing by the headset microphone system. This calibrated dual microphone audio mixing module, therefore, manages the coverage of both the first microphone and second microphone both using separate range capabilities as well as mixing overlapping range capabilities by considering SNRs, sensitivity levels, and AOP. Speech input levels in between the low decibel range threshold (e.g., 70 dB) and the high decibel range threshold (e.g., 90 dB) are calibrated and mixed based on the SNR and sensitivity levels of both the first microphone and second microphone. In an embodiment, the execution of the computer-readable program code of the dual microphone audio mixing module by the digital signal processor extends the output level at the floor and ceiling speech levels thereby increasing the speech range detectable by the headset microphone system. This increases the audio detection capabilities of the headset microphone system as well as increases the user satisfaction during operation of the information handling system. Again, other audio processing may be conducted prior to the output being provided to the speaker. This other audio processing may again include execution of the computer-readable program code of the AEC/NR module and AGC module as described herein in order to mitigate or eliminate echo and noise within the audio signal from the second microphone as well as adjust the power or amplitude of the audio signal where necessary.

After these three different types of audio signals have been processed and sent, concurrently, to an output device such as the speaker, the method 500 includes, at block 555 a determination as to whether the information handling system and headset microphone system is still initiated. Where the information handling system and headset microphone system is still initiated, the method 500 continues to block 510 as described herein. Where the information handling system is no longer initiated at block 555, the method 500 ends here.

The blocks of the flow diagrams of FIG. 5 or steps and aspects of the operation of the embodiments herein and discussed herein need not be performed in any given or specified order. It is contemplated that additional blocks, steps, or functions may be added, some blocks, steps or functions may not be performed, blocks, steps, or functions may occur contemporaneously, and blocks, steps, or functions from one flow diagram may be performed within another flow diagram.

Devices, modules, resources, or programs that are in communication with one another need not be in continuous communication with each other, unless expressly specified otherwise. In addition, devices, modules, resources, or programs that are in communication with one another can communicate directly or indirectly through one or more intermediaries.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The subject matter described herein is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents and shall not be restricted or limited by the foregoing detailed description.

What is claimed is:

1. A headset microphone system comprising:
a digital signal microprocessor;
a microphone system power management unit (PMU) to provide power to the digital signal microprocessor;
a first microphone to receive voice input from a user at a first speech decibel range;
a second microphone to receive voice input from a user at a second speech decibel range;
the digital signal microprocessor to generate an audio stream output from the voice input including a mixed audio output, where the digital signal processor executes computer-readable program code of a dual microphone audio mixing module to mix portions of voice input from each of the first microphone and second microphone to the mixed audio output when the voice input detected at the first microphone exceeds a low decibel range threshold and the audio detected at the second microphone falls below a high decibel range threshold.

2. The headset microphone system claim 1 further comprising:
a high gain amplifier operatively coupled to the first microphone to increase the amplitude of the signal received at the first microphone to receive the voice input in a lower decibel range than the second microphone; and
a first dynamic range controller operatively coupled to the high gain amplifier to set the low decibel range threshold for the first microphone.

3. The headset microphone system of claim 1 further comprising:
a low gain amplifier operatively coupled to the second microphone to increase the amplitude of the signal received at the second microphone to receive the voice input in a higher decibel range than the first microphone; and
a second dynamic range controller operatively coupled to the low gain amplifier to set the high decibel range threshold for the second microphone.

4. The headset microphone system of claim 1 further comprising:
wherein the high decibel range threshold is 90 decibels and the low decibel range threshold is 70 decibels.

5. The headset microphone system of claim 1 further comprising:
the digital signal microprocessor executing computer-readable program code of an anti-echo cancelation and noise reduction module to process the audio stream output from the first microphone or the second microphone including the mixed audio output from the dual microphone audio mixing module to reduce echo and noise.

6. The headset microphone system of claim 5 further comprising:
the digital signal microprocessor to execute computer readable program code of an automatic gain control module to maintain the audio stream output from an anti-echo cancelation and noise reduction module to an operatively coupled information handling system.

7. The headset microphone system of claim 1, wherein the execution of the computer-readable program code of the dual microphone audio mixing module by the digital signal microprocessor outputs the audio stream output including a first audio stream from the first microphone when the voice input falls below the low decibel range threshold and a second audio stream from the second microphone when the voice input exceeds the high decibel range threshold to the information handling system.

8. A method of increasing a speech output range for a headset microphone system of a headset device comprising:
receiving voice input from a user at a first microphone of the headset microphone system having a first decibel range and mounted on a boom of the headset device;
receiving the voice input at a second microphone of the headset microphone system having a second decibel range and mounted on the boom of the headset device;
executing computer-readable program code of a dual microphone audio mixing module, via a digital signal microprocessor, to mix voice input from each of the first microphone and the second microphone to a mixed audio output when the voice input detected at the first microphone exceeds a low decibel range threshold and when the voice input detected at the second microphone falls below a high decibel range threshold.

9. The method of claim 8 further comprising:
with a high gain amplifier operatively coupled to the first microphone, increasing the amplitude of the signal received at the first microphone to receive the voice input in a lower decibel range than the second microphone; and
setting the low decibel range threshold for the first microphone at a first dynamic range controller operatively coupled to the high gain amplifier.

10. The method of claim 8 further comprising:
with a low gain amplifier operatively coupled to the second microphone, increasing the amplitude of the signal received at the second microphone to receive the voice input in a higher decibel range than the first microphone; and
setting the high decibel range threshold for the second microphone at a second dynamic range controller operatively coupled to the low gain amplifier.

11. The method of claim 8 further comprising:
executing computer-readable program code, via the digital signal microprocessor, of a low and high threshold detection module to detect when the voice input detected at the first microphone exceeds a low decibel range threshold and the voice input detected at the second microphone falls below a high decibel range and cause the dual microphone audio mixing module to mix the voice input from each of the first microphone and second microphone for further signal processing by the digital signal processor.

12. The method of claim 8 further comprising:
executing computer-readable program code, via the digital signal microprocessor, of an anti-echo cancelation and noise reduction module to process the mixed audio output from the dual microphone audio mixing module to reduce echo and noise present in the audio stream from the first microphone and second microphone.

13. The method of claim 8 further comprising:
executing computer readable program code, via the digital signal microprocessor, of an automatic gain control module to maintain a signal output from the anti-echo cancelation and noise reduction module to the information handling system.

14. The method of claim 8, wherein the executing of the computer-readable program code of the dual microphone audio mixing module by the digital signal microprocessor generates a first audio stream from a first microphone when the voice input falls below the low decibel range threshold and a second audio stream from the second microphone when the voice input exceeds the high decibel range threshold to the information handling system.

15. A headset operatively coupled to an information handling system, comprising:
a digital signal microprocessor and at least one speaker;
a headset microphone system including a first microphone to receive voice input from a user at a first speech decibel range and a second microphone to receive the voice input from the user at a second speech decibel range, where the first microphone and the second microphone are mounted to a boom of the headset; and
the digital signal microprocessor to execute computer-readable program code of a dual microphone audio mixing module to mix portions of voice input from each of the first microphone and second microphone into a mixed audio output when the voice input detected at the first microphone exceeds a low decibel range threshold and the voice detected at the second microphone falls below a high decibel range threshold.

16. The headset of claim 15 further comprising:
a high gain amplifier operatively coupled to the first microphone to increase the amplitude of the signal received at the first microphone; and
a first dynamic range controller operatively coupled to the high gain amplifier to set the low decibel range threshold for the first microphone.

17. The headset of claim 15 further comprising:
a low gain amplifier operatively coupled to the second microphone to increase the amplitude of the signal received at the second microphone; and
a second dynamic range controller operatively coupled to the low gain amplifier to set the high decibel range threshold for the second microphone.

18. The headset of claim 16, wherein the execution of the computer-readable program code of the dual microphone audio mixing module by the digital signal microprocessor outputs a first audio stream from the first microphone when the voice input that falls below the low decibel range threshold and second audio stream from the second microphone when the voice input exceeds the high decibel range threshold to the information handling system.

19. The headset of claim 16 further comprising:
the digital signal microprocessor to execute computer-readable program code of a low and high threshold detection module to detect when the voice input detected at the first microphone exceeds a low decibel range threshold and when the voice input detected at the second microphone falls below a high decibel range and cause the dual microphone audio mixing module to mix the voice input from each of the first microphone and second microphone into the mixed audio output.

20. The headset of claim 16 further comprising:
a headband operatively coupled to a first earpiece and a second earpiece; and
the boom including a mouthpiece operatively coupled to the first earpiece at a first end of the mouthpiece and operatively coupled to the second earpiece at a second end of the mouthpiece, wherein the mouthpiece orients the first microphone and second the microphone a locations in front of the user's mouth.
